(19) United States
(12) Patent Application Publication
(10) Pub. No.: US 2006/0071325 A1
(43) Pub. Date: Apr. 6, 2006

(54) Semiconductor device and electronic apparatus

(76) Inventor: Yasuhiko Tanaka, Nara-ken (JP)

Correspondence Address: HARNESS, DICKEY & PIERCE, P.L.C., P.O. BOX 8910, RESTON, VA, 20195, US

(21) Appl. No.: 11/241,972

(22) Filed: Oct. 4, 2005

(30) Foreign Application Priority Data
Oct. 5, 2004 (JP) P2004-292435

(51) Int. Cl. H01L 23/34

(52) U.S. Cl. 257/712

(57) ABSTRACT

A semiconductor device is provided with a heat dissipation metal plate which improves heat dissipation performance in heat generating members of a semiconductor element and the like. In particular, the heat dissipation metal plate is placed on a surface of an insulating film, the surface being located on an opposite side to the semiconductor element. This plate makes it possible to provide the semiconductor device and an electronic apparatus with the same demonstrating the superiority in heat dissipation performance when heat is discharged from the semiconductor element and the like.

### CROSS-REFERENCE TO RELATED APPLICATIONS

This nonprovisional application claims priority under 35 U.S.C. §119(a) on Patent Application No. 2004-292435 filed in Japan on Oct. 5, 2004, the entire contents of which are hereby incorporated by reference.

### BACKGROUND OF THE INVENTION

The present invention relates to a semiconductor device and an electronic apparatus equipped with the semiconductor device. For details, the present invention relates to a semiconductor device referred to as COFs (Chip On Films), in which a semiconductor element is placed on an insulating film formed of an organic material having wiring formed, and an electronic apparatus equipped with the semiconductor device.

Conventionally, there have been TCPs (Tape Carrier Packages) as semiconductor devices in which a semiconductor element is placed on an insulating film having wiring formed.

FIGS. 10A and 10B are views showing the general structure of a TCP. In more detail, FIG. 10A is a cross sectional view of a conventional TCP, and FIG. 10B is a top plan view of the conventional TCP.

The TCP includes a semiconductor element 101, an insulating film 103, wiring (inner leads) 104, a solder resist 105 and a resin 106.

The semiconductor element 101 includes a main body part 111 and bump electrodes 112 extending from the main body part 111. The insulating film 103 has a through-hole in which the semiconductor element 101 is placed. Each of the wiring 104 consists of a portion placed on the insulating film 103 through an adhesive 109 and a portion protruding from the insulating film 103 in a cantilever shape. The solder resist 105 is placed on a part of the insulating film 103 and a part of the wiring 104. The resin 106 is placed around the periphery of the through-hole in order to fix the semiconductor element 101 to the insulating film 103.

The bump electrodes 112 of the semiconductor element 101 are each connected to the portions of the wiring 104 protruding in a cantilever shape from a side where the wiring 104 are not placed on the insulating film 103.

In the TCP, the wiring 104 is placed on the thin insulating film 103, whereby the thickness of an electrical circuit is markedly reduced.

A COF (Chip on Film) is exemplified as another semiconductor device different from the TCP in which the semiconductor element is connected to the insulting film, on which the wiring is formed.

FIGS. 11A and 11B are views showing the general structure of a conventional COF. In more detail, FIG. 11A is a cross sectional view of the conventional COF, and FIG. 11B is a top plan view of the conventional COF.

The COF is different from the TCP in that no through-hole is present at a portion of an insulating film opposed to a semiconductor element, and that portions of wiring 124 connected to bump electrodes 132 on the semiconductor element 121 are backed by the insulating film 123.

In more detail, the COD includes the semiconductor element 121, the insulating film 123, the wiring 124, a solder resist 125 and a resin 126. The semiconductor element 121 has a main body part 131 and the bump electrodes 132.

The wiring 124 is placed on one side surface of the insulating film 123, and the solder resist 125 is placed on a part of the insulating film 123 and a part of the wiring 124.

A main body part 131 of the semiconductor element 121 is placed on the side of the insulating film 123 where the wiring 124 is patterned. The bump electrodes 132 are connected to the wiring 124 on the insulating film 123. The resin 126 is placed around the periphery of the semiconductor element 121 and plays a role of fixing the semiconductor element 121 to the insulating film 123.

However, the TCP shown in FIGS. 10 A and B and the COF shown in FIG. 11 have the problem that heat generated due to operation of the semiconductor element 101, 121 can be cooled only by heat conduction and heat dissipation of the wiring 104, 124, the insulating film 103, 123, and the sealing resin 106, 126. Therefore, measures for heat dissipation have conventionally been taken by installing a metal plate for heat dissipation or a heat dissipation fan or by changing the shape of a casing in an electronic apparatus on which the COF or TCP is mounted.

FIG. 12 shows an electronic apparatus in which a conventional heat dissipation metal plate 140 is installed.

The electronic apparatus includes a casing 149, a COF semiconductor device 148, a heat dissipation plate 140 and an insulating film 141. The COF semiconductor device 148 is placed on the insulating film 141. The heat dissipation plate 140 is placed on the insulating film 141 of the side opposite to the side of the COF device. The heat dissipation plate 140 forms a part of an outer wall of the electronic apparatus.

In this electronic apparatus, the COF semiconductor device 148 is placed on the heat dissipation plate 140 that forms the part of the outer wall of the electronic apparatus through the insulating film 141, whereby heat generated in the semiconductor device 148 is discharged through the heat dissipation plate 140.

However, in recent years, high-density mounting of electronic components in an electronic apparatus is required as a result of an increase in the number of functions and a reduction in the size of electronic apparatuses, and there is a problem that sufficient measures for heat dissipation are not taken with the provision of the heat dissipation plate 140 and so on.

With the prevalence of multioutput semiconductor elements, there is also a limit in reducing the generation of heat in a semiconductor element itself in operation of the semiconductor element.

JP2001-308239A and JP5-326620A are exemplified as literatures of the above prior art.

### SUMMARY OF THE INVENTION

An object of the present invention is therefore to provide a semiconductor device excellent in heat dissipation of the heat discharged from a semiconductor element, and an electronic apparatus provided with the semiconductor device.

In order to solve the above problem, the present invention provides a semiconductor device comprising:
an insulating film;
wiring placed on one side surface of the insulating film;
one or a plurality of semiconductor elements placed in such a manner as to be opposed to the one side surface of the insulating film; and
a heat dissipation member placed on other side surface of the insulating film.

In the present specification, the semiconductor element may be a junction type transistor, a transistor such as a field effect type transistor, a rectifier diode, a light-emitting diode, a diode such as a photodiode, a memory element, an active element such as an IC (integrated circuit).

According to the present invention, since the heat dissipation plate is provided on the surface of the insulating film of the side opposite to the mounting surface of the semiconductor element, heat discharged by the semiconductor element and transferred through the insulating film can be dissipated by the heat dissipation plate. Therefore, since a temperature increase of the semiconductor device can be suppressed, a malfunction of the semiconductor element as a result of the increase in the temperature of the semiconductor element, which is attributed to generation of heat in operation of the semiconductor element, can be prevented.

According to the present invention, since the heat dissipation effect can be improved, the more semiconductor elements can be mounted in the same volume of space. Thus, high-density arrangement of semiconductor elements can be performed on the insulating film.

In one embodiment of the present invention, the heat dissipation member is placed at least at a place corresponding to the semiconductor element on the other side surface of the insulating film.

According to the above embodiment, since the heat dissipation member is at least placed at a place corresponding to the semiconductor element on the other side surface of the insulating film, the distance between the semiconductor element as a heat source and the heat dissipation member can be reduced. Therefore, the heat dissipation performance can further be improved.

In one embodiment of the present invention, the heat dissipation member is placed at least at a place corresponding to the wiring on the other side surface of the insulating film.

According to the above embodiment, since the heat dissipation member is at least placed at a place corresponding to the wiring on the other side surface of the insulating film, the distance between the semiconductor element as a heat source and the heat dissipation member can be reduced. Therefore, the heat dissipation performance can further be improved.

In one embodiment of the present invention, the heat dissipation member is composed of a plurality of portions which are discontinuous with one another.

In the case where a plurality of semiconductor elements are placed on one side surface of the insulating film, if heat dissipation members are placed separately at a plurality of portions of the other side surface thereof corresponding to the semiconductor elements, portions which are subjected to high temperatures can selectively be cooled, and material costs can also be reduced.

In one embodiment of the present invention, the semiconductor device includes at least two types of semiconductor elements.

In one embodiment of the present invention, a bump electrode of the semiconductor element is connected to the wiring by Au—Sn alloy bonding.

According to the above embodiment, since the bump electrode of the semiconductor element is connected to the wiring by Au—Sn alloy bonding, the bump electrodes can firmly be bonded to the wiring.

In one embodiment of the present invention, a bump electrode of the semiconductor element is connected to the wiring by Au—Au alloy bonding.

According to the above embodiment, since the bump electrode of the semiconductor element is connected to the wiring by Au—Au alloy bonding, the bump electrodes can firmly be bonded to the wiring.

In one embodiment of the present invention, a bump electrode of the semiconductor element is connected to the wiring through an anisotropic conductive adhesive film.

According to the above embodiment, since the bump electrode of the semiconductor element is connected to the wiring through an anisotropic conductive adhesive film, the bump electrodes can firmly be bonded to the wiring.

In one embodiment of the present invention, a bump electrode of the semiconductor element is connected to the wiring through an anisotropic conductive adhesive paste.

According to the above embodiment, since the bump electrode of the semiconductor element is connected to the wiring through an anisotropic conductive adhesive paste, the bump electrodes can firmly be bonded to the wiring.

In one embodiment of the present invention, a bump electrode of the semiconductor element is connected to the wiring through a non-conductive adhesive paste.

According to the above embodiment, since the bump electrode of the semiconductor element is connected to the wiring through a non-conductive adhesive paste, the bump electrodes can firmly be bonded to the wiring.

In one embodiment of the present invention, a bump electrode of the semiconductor element is connected to the wiring through a non-conductive adhesive film.

According to the above embodiment, since the bump electrode of the semiconductor element is connected to the wiring through a non-conductive adhesive film, the bump electrodes can firmly be bonded to the wiring.

In one embodiment of the present invention, the wiring is placed directly on the one side surface of the insulating film, and the heat dissipation member is placed directly on the other side surface of the insulating film.

According to the above embodiment, since the wiring is directly placed on the one side surface of the insulating film, and the heat dissipation member is directly placed on the other side surface of the insulating film, it is surely possible to prevent the wiring from being electrically connected to the heat dissipation member, as well as prevent the semiconductor device from being damaged.

In one embodiment of the present invention, the wiring is placed on the one side surface of the insulating film through an adhesive, while the heat dissipation member is placed on the other side surface of the insulating film through the adhesive.

According to the above embodiment, since the wiring is placed on the one side surface of the insulating film through an adhesive, while the heat dissipation member is placed on the other side surface of the insulating film through the adhesive, connection between the wiring and the insulating film can be made firm, and also connection between the heat dissipation member and the insulating film can be made firm.

In one embodiment of the present invention, a passive element is placed on the insulating film.

In this specification, the passive element may be a capacitor, a resistor or a coil.

When the passive element is placed on the insulating film, the semiconductor is apt to be subjected to high temperatures because heat is discharged from the passive element besides the semiconductor element. This makes the significance of placing the heat dissipation member large.

In one embodiment of the present invention, an insulating thin-film resin is applied to a part of or an entire surface of the heat dissipation member; or
an insulating sheet member is pasted on a part of or an entire surface of the heat dissipation member.

According to the above embodiment, a short circuit between the heat dissipation member and the wiring or other components can surely be prevented thanks to the thin-film resin or the insulating sheet member.

In one embodiment of the present invention, an electronic apparatus comprising the above-stated semiconductor device and a heat dissipation component, wherein the heat dissipation member of the semiconductor device is directly or indirectly connected to the heat dissipation component.

According to the present invention, since the semiconductor device of the above invention is equipped, the heat dissipation effect can be made large, and a failure attributable to the temperature increase can surely be prevented.

As described above, according to the present invention, a large quantity of heat can be discharged through the heat dissipation member. Therefore, the heat dissipation performance can markedly be improved, compared with the conventional semiconductor device that only has a heat dissipation method using the heat conduction or heat dissipation from the wiring, insulating film, resin and semiconductor element.

According to the present invention, since the semiconductor device has large heat dissipation performance, measures for the heat dissipation in electronic apparatuses on which semiconductor devices are mounted can be reduced, and semiconductor devices can be mounted on an electronic apparatus highly densely.

When using materials having high thermal conductivity for materials of the heat dissipation member, the heat dissipation performance of the semiconductor device can be improved, and a malfunction of the semiconductor element as a result of the increase in the temperature of the semiconductor element can be prevented, and the more semiconductor elements can be mounted in the same volume of space.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIGS. 1 A, B and C are views showing a semiconductor device according to a first embodiment of the present invention;

FIGS. 2 A and B are cross sectional views showing a semiconductor device of a comparative example;

FIGS. 3 A and B are views showing a semiconductor device according to a second embodiment of the present invention;

FIG. 4 is a view showing a surface of an insulating film of the side opposite to the side of a semiconductor element in a semiconductor device according to a third embodiment of the present invention;

FIGS. 5A, B, C and D are views showing a semiconductor device according to a fourth embodiment of the present invention;

FIGS. 6 A, B and C are views showing a semiconductor device according to a fifth embodiment of the present invention;

FIGS. 7 A, B and C are views showing an example of a method of bonding bump electrodes of a semiconductor element to wiring on an insulating film;

FIG. 8 is a cross sectional view of an electronic apparatus according to the first embodiment;

FIG. 9 is a cross sectional view of an electronic apparatus according to the second embodiment;

FIGS. 10 A and B are views showing the general structure of a conventional TCP;

FIG. 11 is a view showing the general structure of a conventional COF; and

FIG. 12 shows an electronic apparatus in which a conventional heat dissipation metal plate is installed.

### DETAILED DESCRIPTION OF THE INVENTION

Semiconductor laser devices of the present invention will be described in detail by the embodiments below with reference to the drawings.

### First Embodiment

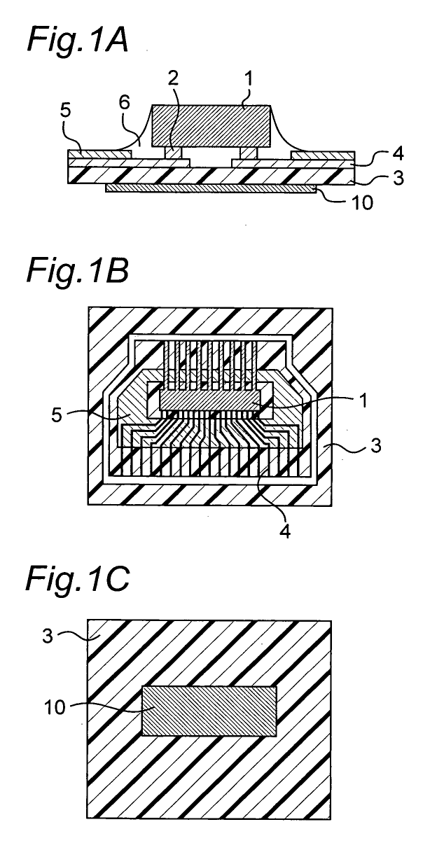

FIG. 1A, B and C are views showing a semiconductor device according to a first embodiment of the present invention. In more detail, FIG. 1A is a cross sectional view of the semiconductor device of the first embodiment. FIG. 1B is a view showing a mounting surface of a semiconductor element in the semiconductor device of the first embodiment. FIG. 1C is a view showing a surface of the side on which the semiconductor element in the semiconductor device of the first embodiment is not mounted.

As shown in FIG. 1A, the semiconductor device includes a semiconductor element 1, an insulating film 3, wiring 4, a solder resist 5, a sealing resin 6 and a heat dissipation metal plate 10 as an example of a heat dissipation member.

The wiring 4 is placed on one side surface of the insulating film 3. The semiconductor element 1 has a main body part 1 and bump electrodes 2. The bump electrodes 2 are each connected to the wiring 4.

As shown in FIG. 1B, the solder resist 5 is placed at a peripheral portion of the semiconductor element 1 on the insulating film 3 so as to serve as a barrier to solder when the semiconductor element 1 is soldered to the wiring 4. The sealing resin 6 is provided in a manner so as to be in contact with the entire side surfaces of the semiconductor element 1 as shown in FIG. 1A. The sealing resin 6 surely fixes the semiconductor element 1 to the insulating film 3.

The heat dissipation plate 10 is placed on a surface of the insulating film 3 of the side opposite to the side of the semiconductor element 1. In more detail, as shown in FIG. 1C, a surface area of the heat dissipation plate 10 is smaller than a surface area of the insulating film 3. The heat dissipation plate 10 is placed at a place corresponding to the semiconductor element 1 on the opposite side surface thereof.

According to the semiconductor of the first embodiment, since the heat dissipation plate 10 is placed on the surface of the insulating film 3 of the side opposite to the mounting surface of the semiconductor element 1, heat discharged from the semiconductor element 1 and conducted through the insulating film 3 can be dissipated by the heat dissipation plate 10. Therefore, since a temperature increase of the semiconductor device 1 can be suppressed, the occurrence of a malfunction of the semiconductor element 1 as a result of an increase in the temperature of the semiconductor element, which is attributed to generation of heat in operation of the semiconductor element 1, can be prevented. Further, the heat dissipation effect can be improved, and the temperature increase due to generation of heat, which is attributed to high-density mounting resulting from an increase in the number of functions and a reduction in the size of electronic apparatuses as well as an increase in the number of outputs in semiconductor elements, can surely be prevented.

According to the semiconductor device of the first embodiment, since the heat dissipation effect can be improved, the more semiconductor elements 1 can be mounted in the same volume of space. Thus, high-density arrangement of the semiconductor elements 1 can be performed on the insulating film.

According to the semiconductor device of the first embodiment, since the heat dissipation plate 10 is placed at a place corresponding to the semiconductor element 1, on a surface of the insulating film, on which the semiconductor element 1 is not mounted. Therefore, the heat dissipation performance can efficiently be improved while keeping the production costs low.

In the semiconductor device 1 of the first embodiment, the heat dissipation plate 10 is placed at the place corresponding to the semiconductor element 1 on the insulating film 3. Alternatively, according to the present invention, the heat dissipation plate may also be placed at places corresponding to the semiconductor element and the wiring on the insulating film. In this case, the heat dissipation performance of the semiconductor device can further be improved.

In the semiconductor device of the first embodiment, the wiring 4 is directly placed on one side surface of the insulating film 3, while the heat dissipation plate 10 is directly placed on the other side surface of the insulating film 3. However, in this invention, the wiring may also be placed on one side surface of the insulating film through an adhesive, while the heat dissipation member may be placed on the other side surface of the insulating film through the adhesive. In this case, it is possible to make a firm connection between the wiring and the insulating film, as well as possible to make a firm connection between the heat dissipation member and the insulating film.

As shown in FIG. 1, in the case of the COF, a portion of the insulating film 3 on which the semiconductor element is to be mounted is not formed with a through-hole, and the wiring 4 referred to as an inner lead, which is to be bonded to the semiconductor element 1, is in a state in which it is backed by the insulating film 3. For that reason, by providing the heat dissipation plate 10 on the opposite surface of the mounting surface of the semiconductor element 1 as shown in FIG. 1, a contact between the wiring 4 and the heat dissipation plate 10 can be prevented, thus making it possible to secure an electrical insulating state.

Therefore, since the heat dissipation effect can be improved by providing the heat dissipation plate 10 on the opposite surface of the mounting surface of the semiconductor element 1 in the COF, it is possible to prevent the occurrence of a malfunction of the semiconductor element 1 as a result of the temperature increase of the semiconductor element 1, which is caused by generation of heat in operation of the semiconductor element 1, and it also becomes feasible to mount the more semiconductor elements 1 in the same volume of space.

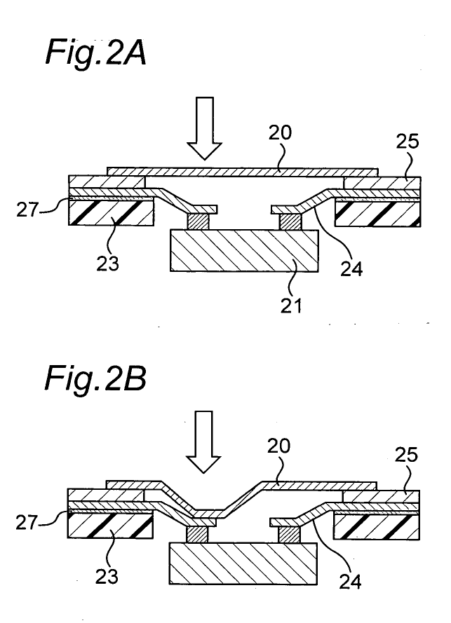

FIG. 2 A is a cross sectional view of a semiconductor device of a comparative example fabricated in order to compare it with the semiconductor device of the present invention. In more detail, it shows a TCP semiconductor device in which a heat dissipation plate 20 is placed.

In the case of the TCP semiconductor device, a portion of an insulating film 23, on which a semiconductor element 21 is mounted, is formed with a through-hole in advance. Tip end portions of wiring 24 is bonded to the semiconductor element 1 in a state in which the wiring 24 referred to as an inner lead that is placed on the insulating film 23 through an adhesive 29 protrude from the insulating film 23 in a cantilever shape. Therefore, when placing the heat dissipation plate 20 on the TCP semiconductor device, there is no placing method but to place its edge portions so that they are bonded to a solder resist 25 placed on the wiring 24 as shown in FIG. 2A.

With such a placing method, however, the wiring 24 is in contact with the heat dissipation plate 20 as shown in FIG. 2B. Thus, there is fear that an electrical short circuit occurs, resulting in the problem that the reliability of the semiconductor device is low.

### Second Embodiment

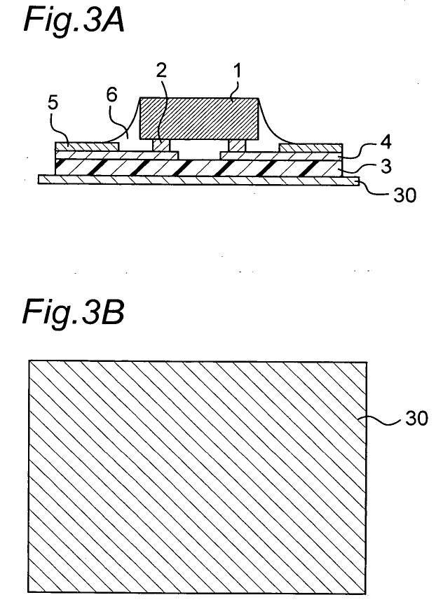

FIGS. 3A and B are views showing a semiconductor device according to a second embodiment of the present invention. In more detail, FIG. 3A is a cross sectional view of the semiconductor device of the second embodiment, and FIG. 3B is a view showing a surface of the side opposite to the side of the mounting surface of the semiconductor element in the semiconductor device of the first embodiment.

The semiconductor device of the second embodiment is the same as the semiconductor device of the first embodiment except for the shape of a heat dissipation plate 30.

In the semiconductor device of the second embodiment, the same components as those of the semiconductor device of the first embodiment are designated by similar numerals, and description thereof is omitted. Further, in the semiconductor device of the second embodiment, description of the effect in common with that of the semiconductor device of the first embodiment is omitted, and only the constitution and effect that are different from those of the semiconductor device of the first embodiment are described.

In the semiconductor device of the second embodiment, as shown in FIG. 2A and FIG. 2B, the heat dissipation plate 30 larger than the insulating film 3 is placed on a surface of the insulating film 3 of the side opposite to the side of the semiconductor element 1.

According to the semiconductor device of the second embodiment, since the heat dissipation plate 30 larger than the insulating film 3 is placed on the surface of the insulating film 3 of the side opposite to the side of the semiconductor element 1, the heat dissipation effect of the heat dissipation plate 30 can markedly improved, thus making it possible to surely prevent the temperature increase due to generation of heat from the semiconductor element 1 in the COF.

### Third Embodiment

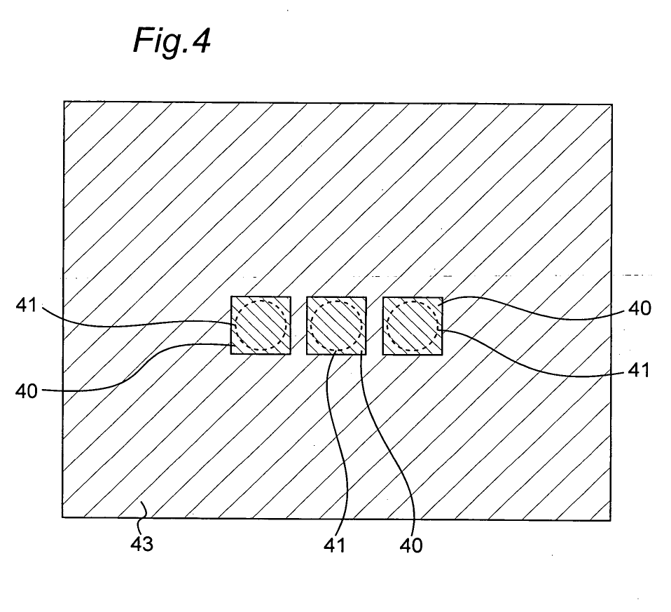

FIG. 4 is a view showing a surface of an insulating film 43 of the side opposite to the side of the semiconductor element in a semiconductor device of a third embodiment.

In FIG. 4, portions 41 shown in dotted lines are those whose temperatures become higher than those of the other portions within the insulating film 43, by the arrangement of heat sources such as semiconductor elements etc. on the insulating film 43.

As shown in FIG. 4, in the semiconductor device of the third embodiment, three square-shaped heat dissipation plates 40 are placed separately in a manner so as to cover the high-temperature portions 41 that are present separately on the surface of the insulating film 43 of the side opposite to the side of the semiconductor element.

As in the semiconductor device of the third embodiment, if the plurality of heat dissipation plates are placed separately in a manner so as to cover the plurality of high-temperature portions that are present separately, the temperature increase of the semiconductor device can efficiently be suppressed, while keeping the production costs of the semiconductor device low.

In the third embodiment, the number of high-temperature portions within the insulating film 43 is three, but the number of high-temperature portions may be two or four or more. Thus, it is a matter of course that the number of heat dissipation members that are placed separately may be two or four or more. Furthermore, the shape of each of the heat dissipation members does not need to be square, and it is a matter of course that any shape, such as circular, other than square may be applicable.

### Fourth Embodiment

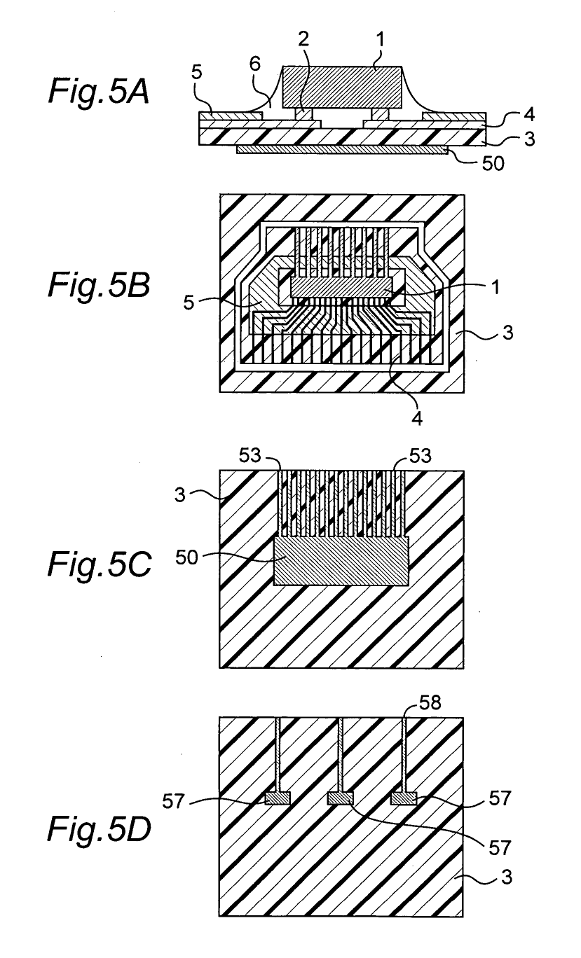

FIGS. 5A, B, C and D are views showing a semiconductor device according to a fourth embodiment. In more detail, FIG. 5A is a cross sectional view of the semiconductor device of the fourth embodiment, FIG. 5B is a top plan view of the side of the semiconductor element in the semiconductor device of the fourth embodiment, and FIG. 5C is a top plan view of the side opposite to the side of the semiconductor element in the semiconductor device of the fourth embodiment.

The semiconductor device of the fourth embodiment is the same as the semiconductor device of the first embodiment except for the shape of a heat dissipation plate 50.

In the semiconductor device of the fourth embodiment, the same components as those of the semiconductor device of the first embodiment are designated by similar numerals, and description thereof is omitted. Further, in the semiconductor device of the fourth embodiment, description of the effect in common with that of the semiconductor device of the first embodiment is omitted, and only the constitution and effect that are different from those of the semiconductor device of the first embodiment are described.

In the semiconductor device of the fourth embodiment, as shown in FIG. 5C, the heat dissipation plate 50 has a shape corresponding to the shape of heat dissipation components in the semiconductor device on the insulating film 3. The heat dissipation plate 50 is placed at a place of a surface of the insulating film 3 of the side opposite to the side of the semiconductor element 1 in the semiconductor device.

End portions 53 of the heat dissipation plate 50 are connected to the heat dissipation components placed on the side of the semiconductor element in the semiconductor device.

According to the semiconductor device of the fourth embodiment, since the heat dissipation plate 50 is directly connected to the heat dissipation components, heat can efficiently be transferred to the heat dissipation plate 50 by heat conduction, so that the conductive heat can be discharged from a surface of the heat dissipation plate 50. Therefore, a temperature increase of the semiconductor device due to generation of heat from the COF semiconductor element can further be efficiently prevented.

In the semiconductor device of the fourth embodiment, the shape of the heat dissipation plate 50 is such that it corresponds to the shape of the heat dissipation components in the semiconductor device and that the heat dissipation plate 50 can be connected to the heat dissipation components directly. In the present invention, the shape of the heat dissipation plate 57 is such that it corresponds to the shape of the high-temperature portions on the insulating film 3 and that the heat dissipation plate 57 can be connected to the heat dissipation components directly through their end portions 58 as shown in FIG. 5D. In this case, the shape of the heat dissipation plate 57 can be made simple. Therefore, the heat dissipation performance can be improved while keeping the production costs low.

### Fifth Embodiment

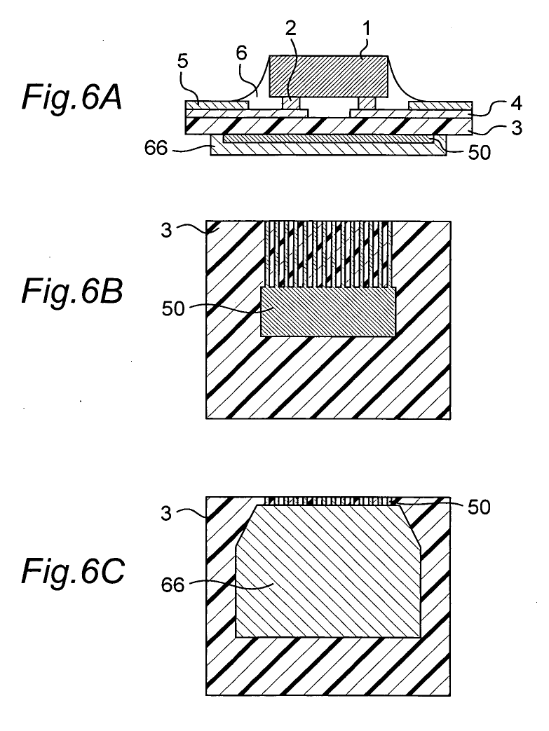

FIGS. 6A, B and C are views showing a semiconductor device according to a fifth embodiment. Describing it in more detail, FIG. 6A is a cross sectional view of the semiconductor device of the fifth embodiment, FIG. 6B is a view showing a surface of an insulating film of the side opposite to the side of the semiconductor element in the semiconductor device of the fifth embodiment during the production. FIG. 6C is a view showing a surface of the insulating film of the side opposite to the side of the semiconductor element in the semiconductor device of the fifth embodiment.

The semiconductor device of the fifth embodiment is the same as the semiconductor device of the fourth embodiment except that an insulating thin-film resin 66 is placed on the surface of the insulating film 3 of the side opposite to the side of the semiconductor element and that the heat dissipation plate 50 is placed on this surface.

In the semiconductor device of the fifth embodiment, the same components as those of the semiconductor device of the fourth embodiment are designated by similar numerals, and description thereof is omitted. Further, in the semiconductor device of the fifth embodiment, description of the effect in common with that of the semiconductor device of the fourth embodiment is omitted, and only the constitution and effect that are different from those of the semiconductor device of the fourth embodiment are described.

In the semiconductor device of the fifth embodiment, an insulating thin-film resin 66 is applied to a place of the heat dissipation plate 50 where a contact with wiring or other components is concerned.

In the semiconductor device of the fifth embodiment, since the insulating thin-film resin 66 is applied to the place of the heat dissipation plate 50 where the contact with the wiring or other components is concerned, a short circuit between the heat dissipation plate 50 and the wiring or other components can be prevented. Therefore, the element characteristics and life reliability of the semiconductor element can be improved.

In the semiconductor device of the fifth embodiment, the insulating thin-film resin 66 is placed on a part of the heat dissipation plate 50 as shown in FIG. 6C. In the present invention, an insulating thin-film resin may also be placed on the entire heat dissipation member. Although the thin-film resin 66 is placed on the part of the heat dissipation plate 50 in the fifth embodiment, an insulating sheet may also be pasted on a part of or the entire heat dissipation member.

In the first to fifth embodiments, only one semiconductor element 1 is placed on the insulating film 3. In the present invention, a plurality of semiconductor elements (e.g., an LED and a transistor) may be placed on the insulating film. If required, a passive element may be placed in addition to the semiconductor element.

In the first to fifth embodiments, the heat dissipation plate is placed on the insulating film 3. Methods of placing the heat dissipation plate on the insulating film 3 include a method of punching out a thin film material such as metal with a die and then pasting it on the insulating film through an adhesive, and a method of pasting an insulating film and a thin film such as metal without using an adhesive, followed by forming a pattern according to the subtractive method.

Other methods include a method of pasting an insulating film and a thin film such as metal through an adhesive, followed by forming a pattern according to the subtractive method, a method of forming a metal pattern on an insulating film according to the semi additive method.

Use of these methods makes it possible to easily place a heat dissipation plate of any shape including a polygonal shape, a circular shape, an elliptical shape or the like on the insulating film.

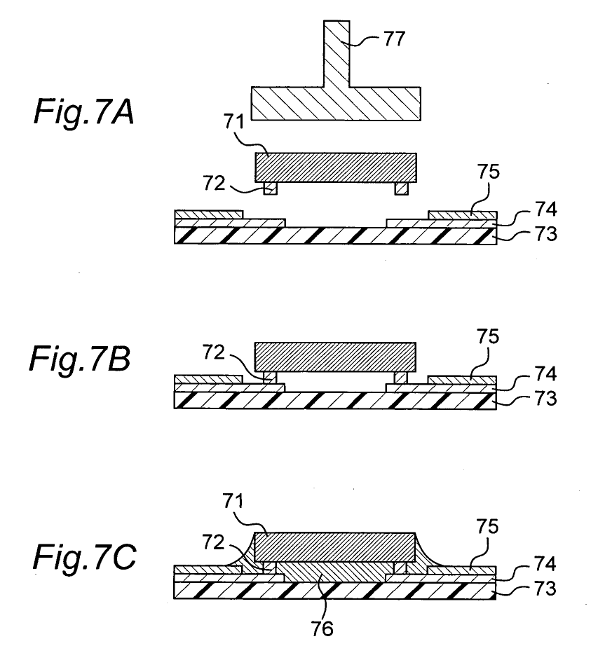

FIGS. 7A, B and C are views showing an example of a method of bonding bump electrodes of a semiconductor element to wiring on an insulating film. The bump electrodes 72 of the semiconductor element 71 shown in FIG. 7 are made of metal.

The method of bonding the bump electrodes 72 to the wiring 74 on the insulating film 73 will hereinafter be described using FIGS. 7A, B and C.

First, as shown in FIG. 7A, the semiconductor element 71 is positioned with respect to the insulating film 73 so that the tin-plated wiring 74 and the gold bump electrodes 72 on the semiconductor element 71 are opposed to each other through an ACF (anisotropic conductive adhesive film).

Thereafter, a surface of the semiconductor element 71 on the side opposite to the side of the bump electrodes 72 is pressed using a pressing member 77, followed by heating for a certain period of time so that the bump electrodes 72 and the wiring 74 is bonded to each other as shown in FIG. 7B. In this manner, the bump electrodes 72 are firmly bonded to the wiring 74.

After that, as shown in FIG. 7C, a sealing resin 76 is injected into a gap formed between the semiconductor element 71 and the insulating film 73 so that the moisture resistance and mechanical strength are improved. In this manner, bonding the bump electrodes 72 to the wiring 74 on the insulating film 73 is completed.

In FIGS. 7A, B and C, reference numeral 75 denotes a solder resist. As shown in FIGS. 7A, B and C, if the solder resist 75 is placed on a portion other than a portion where the bump electrodes 72 are bonded to the wiring 74 on the insulating film 73, conductive foreign matter is in contact with the wiring 74, so that the occurrence of a short circuit in the semiconductor device can surely be prevented.

As in the semiconductor device shown in FIGS. 7A, B and C, when the wiring 74 on the insulating film 73 is positioned with respect to the bump electrode 71 on the semiconductor element 71 through the ACF so that they are opposed to each other, the sealing resin 76 may be omitted.

In the semiconductor device shown in FIGS. 7A, B and C, the wiring 74 is tin-plated. In the present invention, the wiring may be gold-plated. Then, the bump electrodes and the wiring may firmly be bonded to each other using Au—An alloy.

In the semiconductor device shown in FIGS. 7A, B and C, the wiring 74 on the insulating film 73 and the bump electrodes 72 on the semiconductor element 71 are positioned through the ACF so that they are opposed to each other. In the present invention, the wiring on the insulating film and the bump electrodes on the semiconductor element may be positioned so that they are opposed to each other through an ACP (anisotropic conductive adhesive paste), NCP (nonconductive adhesive paste) or nonconductive adhesive film. In these cases, the sealing resin can be omitted as in the case where the ACF is used.

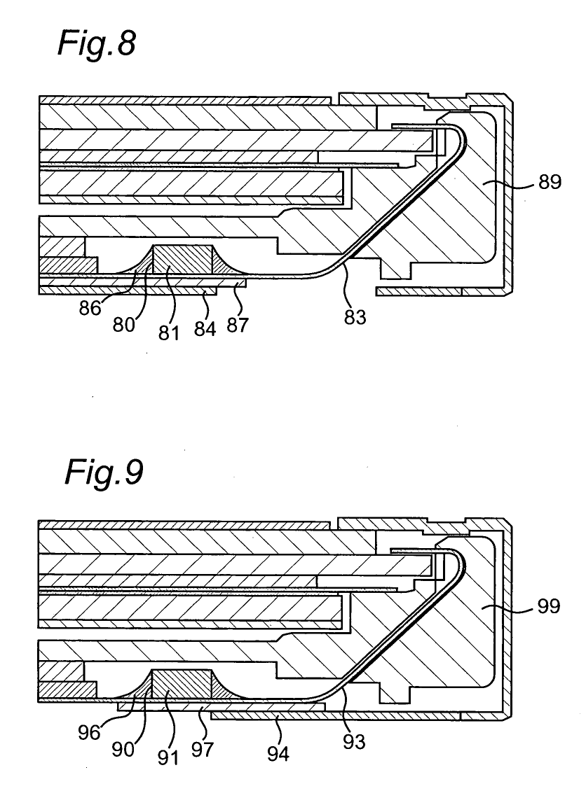

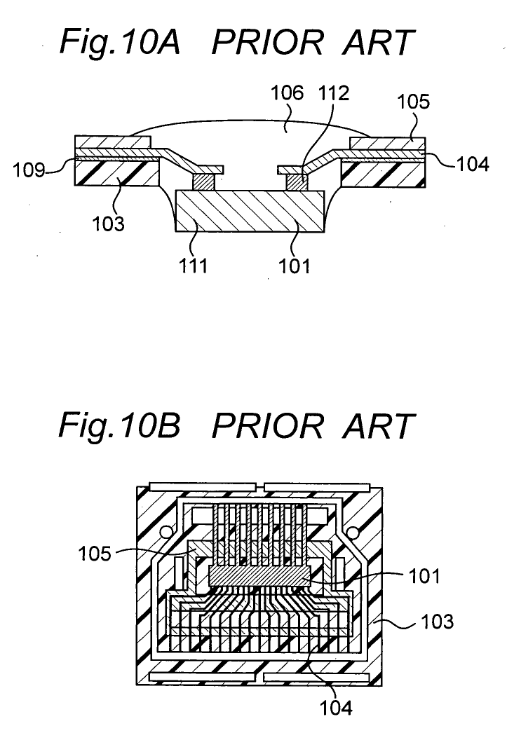

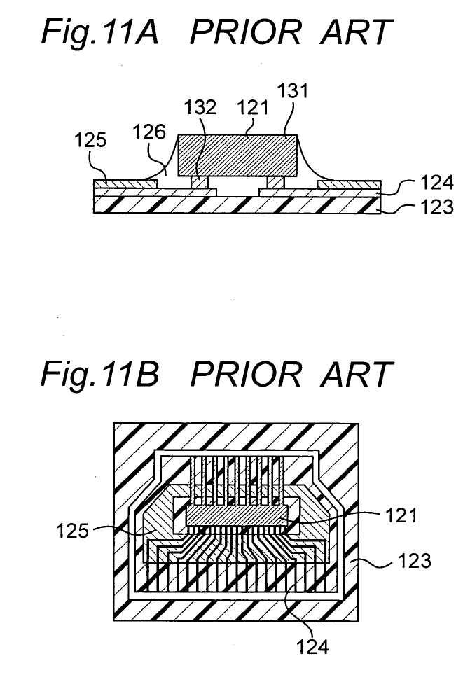

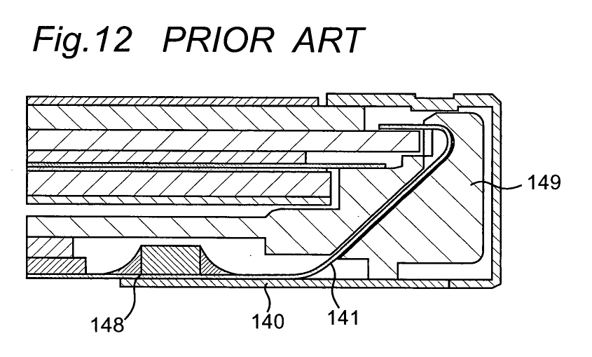

FIG. 8 is a cross sectional view of an electronic apparatus according to a first embodiment equipped with the semiconductor device of the present invention.

This electronic apparatus includes a housing 89, a heat dissipation component 84 constructing a part of an outer wall of the electronic apparatus, and a semiconductor device 80 of the present invention placed within the electronic apparatus.

The electronic apparatus 80 has a semiconductor element 81, an insulating film 83, a sealing resin 86 and a heat dissipation plate 87.

As shown in FIG. 8, in the electronic apparatus of the first embodiment, a large part of the heat dissipation plate 87 is interposed between the insulating film 83 and the heat dissipation component 84.

According to the electronic apparatus of the first embodiment, the heat dissipation plate 87 of the semiconductor device 80 can also efficiently discharge heat in addition to the heat dissipation component 84. Therefore, the temperature increase of the electronic apparatus can further be suppressed.

In the electronic apparatus of the first embodiment, the heat dissipation component 84 is provided at a portion other than the semiconductor device 80. In the present invention, since the semiconductor device of the present invention is provided with measures for heat dissipation, providing a heat dissipation component at the portion other than the semiconductor device is not necessarily required. By omitting the heat dissipation component at the portion other than the portion of the semiconductor device, the production costs of electronic apparatuses can be reduced, and electronic apparatuses can be made compact.

FIG. 9 is a cross sectional view of an electronic apparatus according to a second embodiment equipped with the semiconductor device of the present invention.

In the electronic apparatus of the second embodiment, description of the effect in common with that of the electronic apparatus of the first embodiment is omitted, and only the constitution and effect that are different from those of the semiconductor device of the first embodiment are described.

This electronic apparatus includes a housing 99, a heat dissipation component 94 constructing a part of an outer wall of the electronic apparatus, and a semiconductor device 90 of the present invention placed within the electronic apparatus.

The semiconductor device 90 includes a semiconductor element 91, an insulating film 93, a sealing resin 96 and a heat dissipation plate 97.

As shown in FIG. 9, in the electronic apparatus of the second embodiment, a portion of the heat dissipation plate 97 corresponding to the semiconductor device 91 constructs a part of an outer wall of the electronic apparatus.

According to the electronic apparatus of the second embodiment, since the portion of the heat dissipation plate 97 corresponding to the semiconductor element 91 constructs the part of the outer wall of the electronic apparatus, heat discharged from the semiconductor element 91 can efficiently be discharged to the outside space. Therefore, a temperature increase in the electronic apparatus can further be suppressed.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A semiconductor device comprising:
an insulating film;
wiring placed on one side surface of the insulating film;
one or a plurality of semiconductor elements placed in such a manner as to be opposed to the one side surface of the insulating film; and
a heat dissipation member placed on other side surface of the insulating film.

2. The semiconductor device as claimed in claim 1, wherein
the heat dissipation member is placed at least at a place corresponding to the semiconductor element on the other side surface of the insulating film.

3. The semiconductor device as claimed in claim 2, wherein
the heat dissipation member is placed at least at a place corresponding to the wiring on the other side surface of the insulating film.

4. The semiconductor device as claimed in claim 1, wherein
the heat dissipation member is composed of a plurality of portions which are discontinuous with one another.

5. The semiconductor device as claimed in claim 1, wherein
the semiconductor device includes at least two types of semiconductor elements.

6. The semiconductor device as claimed in claim 1, wherein
a bump electrode of the semiconductor element is connected to the wiring by Au—Sn alloy bonding.

7. The semiconductor device as claimed in claim 1, wherein
a bump electrode of the semiconductor element is connected to the wiring by Au—Au alloy bonding.

8. The semiconductor device as claimed in claim 1, wherein
a bump electrode of the semiconductor element is connected to the wiring through an anisotropic conductive adhesive film.

9. The semiconductor device as claimed in claim 1, wherein
a bump electrode of the semiconductor element is connected to the wiring through an anisotropic conductive adhesive paste.

10. The semiconductor device as claimed in claim 1, wherein
a bump electrode of the semiconductor element is connected to the wiring through a non-conductive adhesive paste.

11. The semiconductor device as claimed in claim 1, wherein
a bump electrode of the semiconductor element is connected to the wiring through a non-conductive adhesive film.

12. The semiconductor device as claimed in claim 1, wherein
the wiring is placed directly on the one side surface of the insulating film, and the heat dissipation member is placed directly on the other side surface of the insulating film.

13. The semiconductor device as claimed in claim 1, wherein
the wiring is placed on the one side surface of the insulating film through an adhesive, while the heat dissipation member is placed on the other side surface of the insulating film through the adhesive.

14. The semiconductor device as claimed in claim 1, wherein
a passive element is placed on the insulating film.

15. The semiconductor device as claimed in claim 1, wherein
an insulating thin-film resin is applied to a part of or an entire surface of the heat dissipation member; or
an insulating sheet member is pasted on a part of or an entire surface of the heat dissipation member.

16. An electronic apparatus comprising the semiconductor device of claim 1 and a heat dissipation component, wherein the heat dissipation member of the semiconductor device is directly or indirectly connected to the heat dissipation component.
